(19) United States
(12) Patent Application Publication
(10) Pub. No.: US 2024/0047528 A1
(43) Pub. Date: Feb. 8, 2024

(54) SEMICONDUCTOR DEVICE INCLUDING TWO-DIMENSIONAL MATERIAL AND METHOD OF MANUFACTURING THE SAME

(71) Applicant: Samsung Electronics Co., Ltd., Suwon-si (KR)

(72) Inventors: Minsu SEOL, Suwon-si (KR); Keunwook Shin, Suwon-si (KR); Alum Jung, Suwon-si (KR); Junyoung Kwon, Suwon-si (KR); Kyung-Eun Byun, Suwon-si (KR); Minseok Yoo, Suwon-si (KR)

(73) Assignee: Samsung Electronics Co., Ltd., Suwon-si (KR)

(21) Appl. No.: 18/156,049

(22) Filed: Jan. 18, 2023

(30) Foreign Application Priority Data
Aug. 3, 2022 (KR) 10-2022-0096993

(51) Int. Cl. H01L 29/786; H01L 29/16; H01L 29/24; H01L 29/66

(52) U.S. Cl. CPC H01L 29/78696; H01L 29/1606; H01L 29/24; H01L 29/66969

(57) ABSTRACT

A semiconductor device may include a two-dimensional (2D) material layer, a source electrode and a drain electrode spaced apart from each other on the 2D material layer, a gate insulating layer and a gate electrode on the 2D material layer between the source electrode and the drain electrode, and graphene layers on both sides of the gate insulating layer. The 2D material layer may include a 2D semiconductor material having a polycrystalline structure. The 2D material layer may include a sheet member and a protrusion. The sheet member may extend along one plane. The protrusion may extend in one direction perpendicular to the one plane. The graphene layer may cover a part of the sheet member and the protrusion.

### CROSS-REFERENCE TO RELATED APPLICATION

This application is based on and claims priority under 35 U.S.C. § 119 to Korean Patent Application No. 10-2022-0096993, filed on Aug. 3, 2022 in the Korean Intellectual Property Office, the disclosure of which is incorporated by reference herein in its entirety.

### BACKGROUND

### 1. Field

The disclosure relates to a semiconductor device including a two-dimensional (2D) material and a method of manufacturing the semiconductor device.

### 2. Description of the Related Art

A transistor is a semiconductor device that performs an electrical switching function, and is used in various semiconductor products such as memories, driving integrated circuits (ICs), etc. When the size of a semiconductor device is reduced, the number of semiconductor devices that may be integrated into one wafer may increase, and the driving speed of the semiconductor device may increase. Accordingly, research for miniaturizing semiconductor devices and improving device integration has been actively conducted.

Recently, research using two-dimensional (2D) materials has been conducted as a solution for miniaturization of semiconductor devices. A 2D material is in the spotlight as a material capable of overcoming the limitation of performance degradation due to a decrease in the size of a semiconductor device because the 2D material has stable and excellent properties even in a thin thickness equal to or less than 1 nm.

### SUMMARY

Provided are a semiconductor device including a two-dimensional (2D) material and a method of manufacturing the semiconductor device.

Additional aspects will be set forth in part in the description which follows and, in part, will be apparent from the description, or may be learned by practice of the presented embodiments of the disclosure.

According to an example embodiment, a semiconductor device may include a two-dimensional (2D) material layer including a 2D semiconductor material having a polycrystalline structure; a source electrode and a drain electrode spaced apart from each other on the 2D material layer; a gate insulating layer and a gate electrode on the 2D material layer between the source electrode and the drain electrode; and graphene layers on both sides of the gate insulating layer. The 2D material layer may include a sheet member and a protrusion. The sheet member may extend along one plane and the protrusion may extend in one direction perpendicular to the one plane. The graphene layers may cover a part of the sheet member and the protrusion.

In some embodiments, the graphene layers may be on the part of the sheet member and an upper portion of the protrusion through a horizontal junction along the one plane and a vertical junction in the one direction perpendicular to the one plane.

In some embodiments, the protrusion may be a single protrusion or a plurality of protrusions.

In some embodiments, the 2D material layer may include a first region and second regions. The first region may correspond to the gate electrode, and the second regions may correspond to the source electrode and the drain electrode. The protrusion may be in the second regions. The graphene layers may be in the second regions between the source electrode and the 2D material layer and between the drain electrode and the 2D material layer.

In some embodiments, a thickness of the sheet member in the first region and a thickness of the sheet member in the second regions may be equal to each other.

In some embodiments, a thickness of the sheet member in the second regions may exceed a thickness of the sheet member in the first region.

In some embodiments, the semiconductor device may further include spacers. The 2D material layer may include a first region and second regions. The first region may correspond to the gate electrode. The second regions may correspond to a region between the source electrode and the gate electrode and a region between the drain electrode and the gate electrode. The protrusion may be in the second regions. The graphene layers may be between the 2D material layer and the spacers in the second regions. The spacers may be between the source electrode and the gate electrode and between the drain electrode and the gate electrode in the second regions.

In some embodiments, the graphene layers may extend under the source electrode and the drain electrode.

In some embodiments, the 2D semiconductor material may include a material having a bandgap greater than or equal to about 0.5 eV and less than or equal to about 3.0 eV.

In some embodiments, the 2D semiconductor material may include transition metal dichalcogenide (TMD) or black phosphorus.

In some embodiments, the TMD may include a metal element and a chalcogen element. The metal element may include at least one of Mo, W, Nb, V, Ta, Ti, Zr, Hf, Tc or Re. The chalcogen element may include at least one of S, Se or Te.

In some embodiments, the 2D material layer may include one to ten layers.

In some embodiments, the 2D material layer may include one to five layers.

In some embodiments, the graphene layers may include graphene, and the graphene may have a crystal size of about 0.5 nm or more and about 500 nm or less.

In some embodiments, the graphene layers may include graphene, and the graphene may have a ratio of carbons having a sp2 combination structure with respect to all carbons of about 50% or more and about 99% or less.

In some embodiments, the graphene layers may include graphene, and the graphene may have hydrogen in a range of about 1 at % or more and about 20 at % or less.

In some embodiments, the semiconductor device may include a mixing region where the 2D material layer and the graphene layers coexist in the one direction. In the mixing region, a content of graphene in the graphene layers may be about 20 vol % or more and about 80 vol % or less.

In some embodiments, the mixing region may include a region of one to five layers.

According to an embodiment, an electronic device may include any one of the semiconductor devices described above.

According to an example embodiment, a method of manufacturing a semiconductor device may include forming a two-dimensional (2D) material layer on a substrate, the 2D material layer including a 2D semiconductor material having a polycrystalline structure, the 2D material layer including a sheet member and a protrusion, the sheet member extending along one plane and the protrusion extending in one direction perpendicular to the one plane; forming a graphene layer covering a part of the sheet member and the protrusion; forming a gate insulating layer and a gate electrode on the 2D material layer; and forming a source electrode and a drain electrode spaced apart from each other on the 2D material layer.

In some embodiments, the forming the graphene layer may include growing graphene in one or more directions from the part of the sheet member and a circumference of the protrusion.

In some embodiments, the protrusion may be a single protrusion or a plurality of protrusions.

In some embodiments, the 2D material layer may include a first region and second regions. The first region may correspond to the gate electrode. The second regions may correspond to the source electrode and the drain electrode. The protrusion may be in the second regions. The graphene layer may be in the second regions between the source electrode and the 2D material layer and between drain electrode and the 2D material layer.

In some embodiments, the forming the graphene layer may be performed using one or more of low temperature chemical vapor deposition (LTCVD), inductively coupled plasma-chemical vapor deposition (ICP-CVD), low pressure chemical vapor deposition (LPCVD), atmospheric pressure chemical vapor deposition (APCVD), metal organic chemical vapor deposition (MOCVD), and plasma-enhanced chemical vapor deposition (PECVD).

In some embodiments, the 2D semiconductor material may include a material having a bandgap of about 0.5 eV to about 3.0 eV.

In some embodiments, the 2D semiconductor material may include transition metal dichalcogenide (TMD) or black phosphorus.

In some embodiments, the 2D semiconductor material layer may include one to ten layers.

In some embodiments, the graphene layer may include graphene, and the graphene may have a crystal size of about 0.5 nm to about 500 nm.

In some embodiments, the graphene layer may include graphene, and the graphene may have a ratio of carbons having a sp2 combination structure with respect to all carbons of about 50% to about 99%.

In some embodiments, the graphene layer may include graphene, and the graphene may have hydrogen in a range of about 1 at % to about 20 at %.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view of a semiconductor device according to an em bodiment;

FIG. 2 schematically illustrates a partial cross-section of a semiconductor device according to an embodiment;

FIG. 3 is a cross-sectional view of a semiconductor device according to another em bodiment;

FIG. 4 is a cross-sectional view of a semiconductor device according to another embodiment;

FIGS. 5A to 5D are diagrams illustrating a method of manufacturing a semiconductor device according to an embodiment;

FIG. 6 is a perspective view illustrating a semiconductor device according to another embodiment;

FIG. 7 is a cross-sectional view taken along line A-A′ of FIG. 6;

FIG. 8 is a perspective view illustrating a semiconductor device according to another embodiment;

FIG. 9 is a cross-sectional view taken along line B-B′ of FIG. 8; and

FIGS. 10 and 11 are conceptual diagrams schematically illustrating an electronic device architecture that may be applied to an electronic device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, embodiments of the disclosure will be described in detail with reference to the accompanying drawings. In the following drawings, like reference numerals refer to like elements, and the size of each component in the drawings may be exaggerated for clarity and convenience of description. The embodiments of the disclosure may be variously modified and may be embodied in many different forms.

Hereinafter, what is described as “upper” or “on” may include those directly above, below, left, and right in contact, as well as above, below, left, and right in non-contact. The singular forms are intended to include the plural forms as well, unless the context clearly indicates otherwise. When a part “comprises” or “includes” an element in the specification, unless otherwise defined, it is not excluding other elements but may further include other elements.

The term “above” and similar directional terms may be applied to both singular and plural. Operations of all methods described herein may be performed in any suitable order unless otherwise indicated herein or otherwise clearly contradicted by context and are not necessarily limited to the described order.

Also, in the specification, the term “unit” or “module” denote a unit or a module that processes at least one function or operation, and may be implemented by hardware, software, or a combination of hardware and software.

Also, the connections of lines and connection members between constituent elements depicted in the drawings are examples of functional connection and/or physical or circuitry connections, and thus, in practical devices, may be expressed as replicable or additional functional connections, physical connections, or circuitry connections.

The use of any and all examples, or example language provided herein, is intended merely to better illuminate the disclosure and does not pose a limitation on the scope of the disclosure unless otherwise claimed.

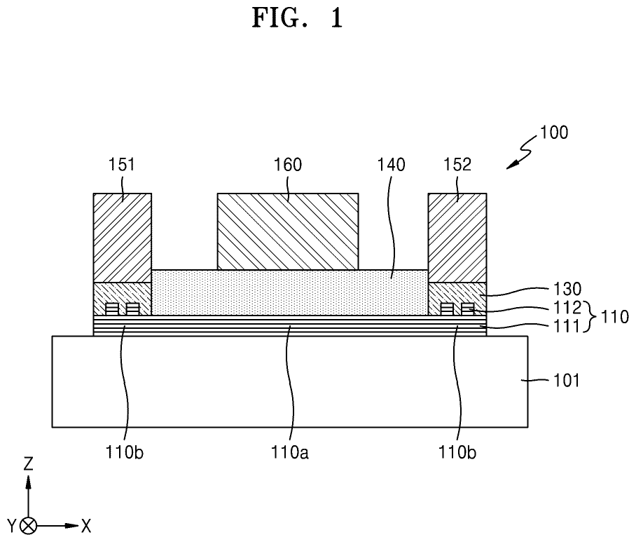

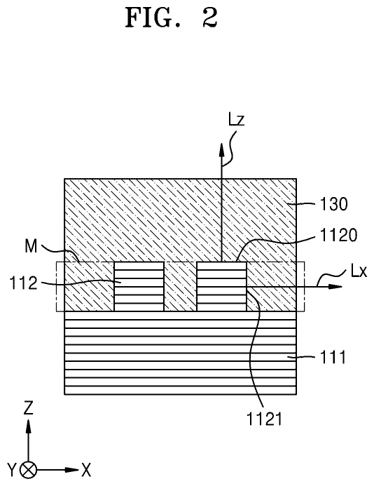

FIG. 1 is a cross-sectional view of a semiconductor device according to an embodiment. FIG. 2 schematically illustrates a partial cross-section of a semiconductor device according to an embodiment. A semiconductor device 100 illustrated in FIG. 1 may be, for example, a field effect transistor (FET).

Referring to FIGS. 1 and 2, a two-dimensional (2D) material layer 110 as a channel layer may be disposed on a substrate 101 according to an embodiment. The substrate 101 may include various materials such as a semiconductor material, an insulating material, and a metal material. When the 2D material layer 110 to be described below is formed by depositing a 2D semiconductor material on the substrate 101, the substrate 101 may be a substrate for growth of the 2D semiconductor material.

The 2D material layer 110 may include a 2D semiconductor material having a polycrystalline structure. The 2D semiconductor material refers to a 2D material having a layered structure in which constituent atoms are two-dimensionally combined. The 2D semiconductor material has excellent electrical properties and may maintain high mobility without significantly changing its properties even when its thickness is reduced to a nanoscale.

The 2D semiconductor material may include a material having a bandgap equal to or greater than about 0.5 eV and equal to or smaller than 3.0 eV. For example, the 2D semiconductor material may include transition metal dichalcogenide (TMD) or black phosphorus. However, the disclosure is not limited thereto.

TMD is a 2D material having semiconductor properties, and is a compound of a transition metal and a chalcogen element. Here, the transition metal may include, for example, at least one of Mo, W, Nb, V, Ta, Ti, Zr, Hf, Co, Tc, or Re, and the chalcogen element may include, for example, at least one of S, Se, or Te. As a specific example, TMD may include MoS₂, MoSe₂, MoTe₂, WS₂, WSe₂, WTe₂, ZrS₂, ZrSe₂, HfS₂, HfSe₂, NbSe₂, ReSe₂, etc. However, the disclosure is not limited thereto. Black phosphorus is a semiconductor material having a structure in which phosphorus (P) atoms are two-dimensionally combined.

The 2D semiconductor material may be doped with a p-type dopant or an n- type dopant to control mobility. The 2D material layer 110 may have a monolayer or multilayer structure, where each layer may have an atomic level thickness. The 2D material layer 110 may include, for example, one to ten layers. As a specific example, the 2D material layer 110 may include one to five layers. However, the disclosure is not limited thereto.

The 2D material layer 110 may include a first region 110a and second regions 110b provided on both sides of the first region 110a. The first region 110a may be located in the center of the 2D material layer 110. According to an embodiment, the first region 110a may be a channel region corresponding to a gate electrode 160 to be described below. The second regions 110b may be respectively located on both sides of the 2D material layer 110. According to an embodiment, the second region 110b may be a source region and a drain region respectively provided to correspond to a source electrode 151 and a drain electrode 152 to be described below.

Graphene layers 130 may be disposed on both sides of a gate insulating layer 140, and may be disposed to cover a part of a sheet member 111 and a protrusion 112 included in the 2D material layer 110. According to an embodiment, the graphene layers 130 may be disposed in the second regions 110b respectively located on both sides of the 2D material layer 110 with the gate insulating layer 140 disposed therebetween. Graphene included in the graphene layers 130, according to an embodiment, may be a stable 2D material having one atomic layer. As an example, graphene included in the graphene layers 130 may include crystals with the size equal to or greater than about 0.5 nm and equal to or smaller than about 500 nm. In addition, in the graphene, a ratio of carbons having a sp2 combination structure with respect to all carbons may be equal to or greater than about 50% and equal to or less than about 99%. In addition, graphene may include hydrogen equal to or greater than about 1 at % and equal to or smaller than about 20 at %. In addition, graphene may have a density equal to or greater than about 1.6 g/cc and equal to or smaller than about 2.1 g/cc. In addition, graphene very easily grows one-dimensionally or two-dimensionally because graphene includes only carbon which is a relatively lightweight element. Accordingly, the graphene layers 130 may grow in one or more directions from one surface of the 2D material layer 110 disposed in the second region 110b, for example, the source region and the drain region.

The graphene layers 130 according to an embodiment may include low temperature chemical vapor deposition (LTCVD), inductively coupled plasma- chemical vapor deposition (ICP-CVD), low pressure chemical vapor deposition (LPCVD), atmospheric pressure chemical vapor deposition (APCVD), metal organic chemical vapor deposition (MOCVD), or plasma-enhanced chemical vapor deposition (PECVD), etc., but are not limited thereto.

As described above, the graphene layers 130 of sem imetal property may be disposed between the 2D material layer 110 and the source electrode 151 and the drain electrode 152 including a metal material to be described below, and thus, Fermi-level pinning of the 2D material layer 120 may be limited and/or suppressed. Accordingly, the contact resistance may be reduced in the second region 110b of the 2D material layer 110, that is, the source region and the drain region.

The gate insulating layer 140 and a gate electrode 160 may be sequentially stacked on the first region 110a of the 2D material layer 110. The gate insulating layer 140 may include, for example, silicon nitride, etc., but is not limited thereto.

The gate electrode 160 may include a metal material or a conductive oxide. Here, the metal material may include, for example, at least one selected from the group consisting of Au, Ti, TiN, TaN, W, Mo, WN, Pt, and Ni. In addition, the conductive oxide may include, for example, indium tin oxide (ITO), indium zinc oxide (IZO), etc. However, this is merely an example.

The source electrode 151 and the drain electrode 152 are respectively provided on both sides of the gate electrode 160. The source electrode 151 and the drain electrode 152 are provided in the second region 110b of the 2D material layer 110, that is, the source region and the drain region. Here, the source electrode 151 may be provided to contact the source region of the 2D material layer 110, and the drain electrode 152 may be provided to contact the drain region of the 2D material layer 110. The source electrode 151 and the drain electrode 152 may include, for example, a metal material having excellent electrical conductivity such as Ag, Au, Pt, or Cu, but are not limited thereto.

In the Si-based semiconductor device of the related art, as the channel thickness decreases, the mobility decreases, the threshold voltage distribution increases, and as the channel length decreases, the performance degradation due to the channel effect is severe, and thus, there is a limit to reducing the size of the semiconductor device.

The semiconductor device 100 according to example embodiments may have excellent performance even at a thin thickness equal to or less than 1 nm by using a 2D semiconductor material as a channel, and may also reduce the short channel effect, thereby overcoming the limitation of performance degradation due to the miniaturization of the semiconductor device 100.

The 2D material layer 110 according to an embodiment may include the sheet member 111 and the protrusion 112 disposed on one surface of the sheet member 111. The sheet member 111 according to an embodiment may have a sheet shape extending along one plane (XY plane). The sheet member 111 may include, for example, one to ten layers. As a specific example, the sheet member 111 may include one to five layers. However, the disclosure is not limited thereto.

The protrusion 112 may extend from one surface of the sheet member 111 in one direction (Z direction) perpendicular to one plane (XY plane). According to an embodiment, the protrusion 112 may be formed as a single protrusion or a plurality of protrusions. As an example, the protrusion 112 may be disposed to have a shape having a certain constant pattern. However, the disclosure is not limited thereto, and the protrusion 112 may be disposed to have a shape having an irregular pattern. According to an embodiment, the sheet member 111 and the protrusion 112 may be integrally formed. As another example, the sheet member 111 and the protrusion 112 may be a combination structure in which separate structures are combined. Also, according to an amendment, the sheet member 111 and the protrusion 112 may include the same 2D material. However, the disclosure is not limited thereto, and the sheet member 111 and the protrusion 112 may include different 2D materials.

According to an embodiment, the protrusion 112 may extend in one direction (X direction or Y direction). When a plurality of protrusions 112 extending in one direction (X direction or Y direction) are disposed on one surface of the sheet member 111, a trench shape may be disposed in one surface of the sheet member 111. In addition, according to another example, when the plurality of protrusions 112 extending in one direction (X direction or Y direction) are disposed on one surface of the sheet member 111, a grid shape having a certain pattern may be disposed on one surface of the sheet member 111. In addition, according to another example, when the plurality of protrusions 112 are disposed to be spaced apart from each other on one surface of the sheet member 111, a protruding structure having a certain pattern may be disposed on one surface of the sheet member 111.

According to an embodiment, the protrusion 112 may be formed to have a certain pattern on an upper portion of the sheet member 111 using a certain pattern mask process and an etching process. Also, according to another example, the protrusion 112 may be additionally deposited on a certain pattern region of the sheet member 111 using a certain process. Accordingly, the protrusion 112 may be formed to have a certain pattern on the upper portion of the sheet member 111. However, the disclosure is not limited thereto, and one or more protrusions 112 having an irregular pattern may be formed on one surface of the sheet member 111 in a process of manufacturing the sheet member 111.

As described above, the graphene included in the graphene layer 130 may include only carbon, which is a relatively lightweight element, and may grow very easily one-dimensionally or two-dimensionally. According to an embodiment, the graphene layers 130 may grow in one or more directions from the surface of the 2D material layer 110. As an example, the graphene layers 130 may grow such that a horizontal junction is formed in a first direction Lz with an upper surface of the sheet member 111 extending along one plane (XY plane). In addition, the graphene layers 130 may grow such that a vertical junction is formed with the protrusion 112 in one direction (Z direction) perpendicular to one plane (XY plane). For example, when the cross-section of the protrusion 112 has a rectangular shape in FIG. 2, the graphene layer 130 may grow in the first direction Lz to form a horizontal junction with the upper surface of the sheet member 111 and an upper surface 1120 of the protrusion 112. In addition, the graphene layer 130 may grow in a second direction Lx to form a vertical junction with a side surface 1121 of the protrusion 112. Accordingly, the graphene layers 130 may be disposed on a part of the sheet member 111 and the upper portion of the protrusion 112. In the embodiment described above, the protrusion 112 has been described to have a rectangular cross-section, but the disclosure is not limited thereto. As an example, when the protrusion 112 has a three-dimensional (3D) arbitrary shape, the graphene layers 130 may grow from one surface of the sheet member 111 and the surface of the protrusion 112 in one or more directions.

According to an embodiment, the 2D material layer 110 and the graphene layer 130 may be disposed together in a mixing region M in one direction (Z direction) perpendicular to one plane (XY plane). As described above, the graphene layer 130 may grow from the surfaces of the sheet member 111 and the protrusion 112. Accordingly, the graphene layers 130 may be disposed around the protrusion 112 extending in one direction (Z direction) perpendicular to one plane (XY plane). As an example, the mixing region M may include a region of one or more layers and five or less layers. Also, as an example, the content of graphene in the mixing region M may be equal to or greater than about 20 vol % and equal to or smaller than about 80 vol %.

As described above, the 2D material layer 110 includes the sheet member 111 extending in one plane (XY plane) and the protrusion 112 extending in one direction (Z direction) perpendicular to one plane (XY plane), and thus, the graphene layers 130 may grow in one or more directions. Accordingly, a contact region between the 2D material layer 110 and the graphene layers 130 may increase, and the contact resistance in the second region 110b of the 2D material layer 110, that is, the source region and the drain region, may be reduced.

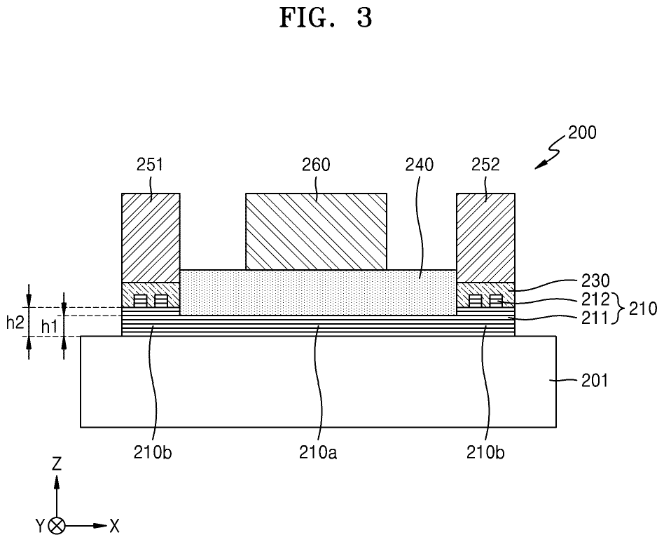

FIG. 3 is a cross-sectional view of a semiconductor device according to another embodiment. Hereinafter, differences from the embodiment described above are mainly described.

Referring to FIG. 3, a 2D material layer 210 according to an embodiment may include a sheet member 211 having different thicknesses according to regions. According to an embodiment, the sheet member 211 may extend along one plane (XY plane). In this regard, the sheet member 211 disposed in a first region 210a that is a channel region may have a first thickness h₁ in one direction (Z direction). Also, the sheet member 211 disposed in a second region 210b that is a source/drain region may have a second thickness h₂ different from the first thickness h₁ in one direction (Z direction). According to an embodiment, the second thickness h₂ may exceed the first thickness h₁. A protrusion 212 and a graphene layer 230 included in the 2D material layer 210 have been described above, and thus, detailed descriptions thereof are omitted.

In the embodiment, the sheet member 211 may have a greater thickness in the second region 210b (the source/drain region) than the first region 210a (the channel region) of the 2D material layer 210. Specifically, the sheet member 211 disposed in the source/drain regions 210a and 210b in which the source/drain electrodes 151 and 152 are disposed may have a relatively great thickness. The sheet member 211 of a greater thickness may be disposed in the second region 210b through an additional deposition process. Accordingly, the contact resistance between the source/drain electrodes 151 and 152 and the source/drain region may be further reduced.

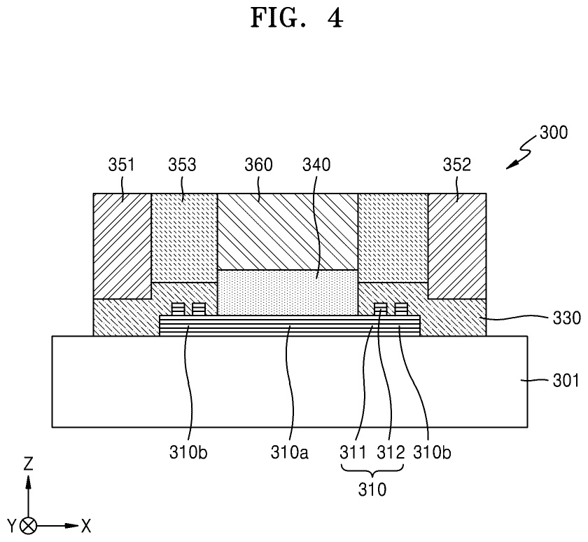

FIG. 4 is a cross-sectional view of a semiconductor device according to another embodiment. Hereinafter, differences from the embodiment described above are mainly described.

Referring to FIG. 4, a 2D material layer 310 may include a first region 310a and second regions 310b provided on both sides of the first region 310a. The first region 310a may be located in the center of the 2D material layer 310. According to an embodiment, the first region 310a may be a channel region corresponding to a gate electrode 360 . The second regions 310b may be respectively located on both sides of the 2D material layer 310. According to an embodiment, the second regions 310b may correspond to regions between a source electrode 351 and a gate electrode 360 and between a drain electrode 352 and the gate electrode 360.

According to an embodiment, spacers 353 may be disposed on the second regions 310b corresponding to the regions between the source/drain electrodes 351 and 352 and the gate electrode 360. The 2D material layer 310 according to an embodiment may include a sheet member 311 extending along the first region 310a and the second region 310b along one plane (XY plane) and a protrusion 312 disposed on the second region 310b. In this regard, the protrusion 312 may be disposed on lower portion of the spacer 353.

According to an embodiment, the graphene layers 330 may extend along a part of the sheet member 311 and a surface of the protrusion 312 in the second region 310b. Accordingly, the graphene layer 330 may be disposed between the spacer 353 and the 2D material layer 310, for example, a part of the sheet member 311 and the protrusion 312 in the second region 310b. Also, the graphene layers 330 may extend to source/drain regions in which the source electrode 351 and the drain electrode 352 are disposed.

In the embodiment, resistance may increase between the source/drain electrodes 351 and 352 on which the spacers 353 are disposed and the gate electrode 360. The 2D material layer 310 including the protrusion 312 between the source/drain electrodes 351 and 352 and the gate electrode 360 may be disposed, and thus, the entire resistance of the semiconductor device may be further reduced.

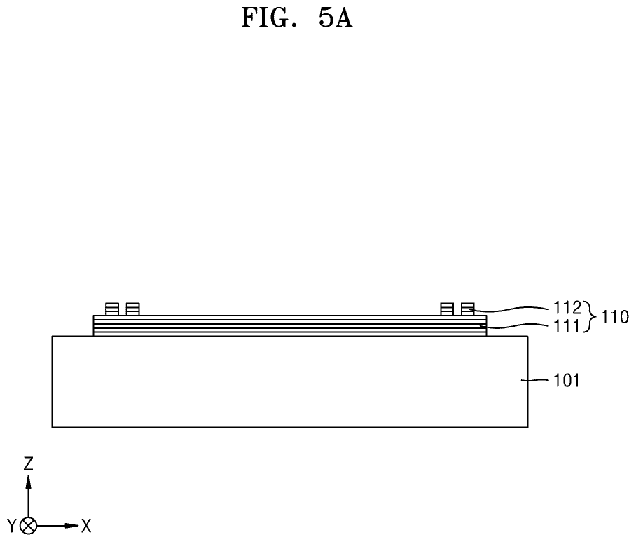

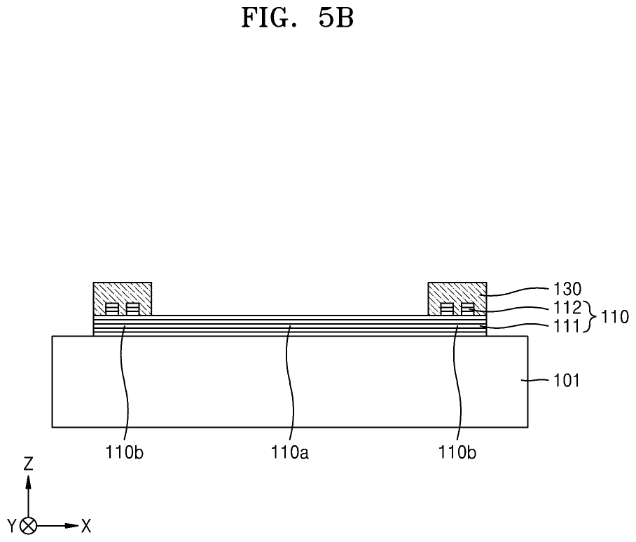

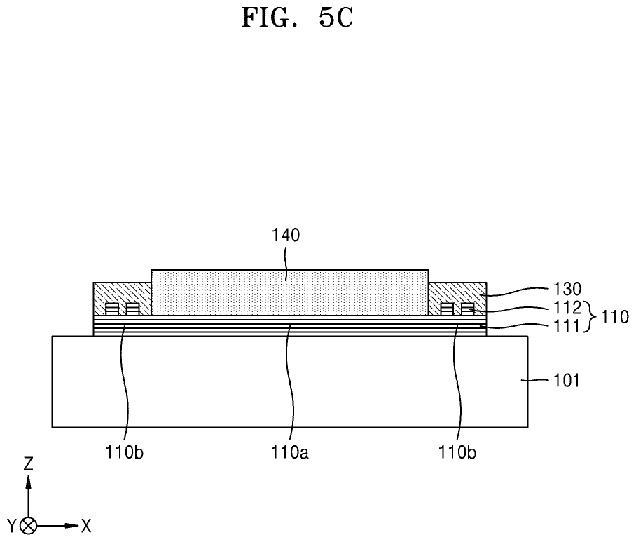

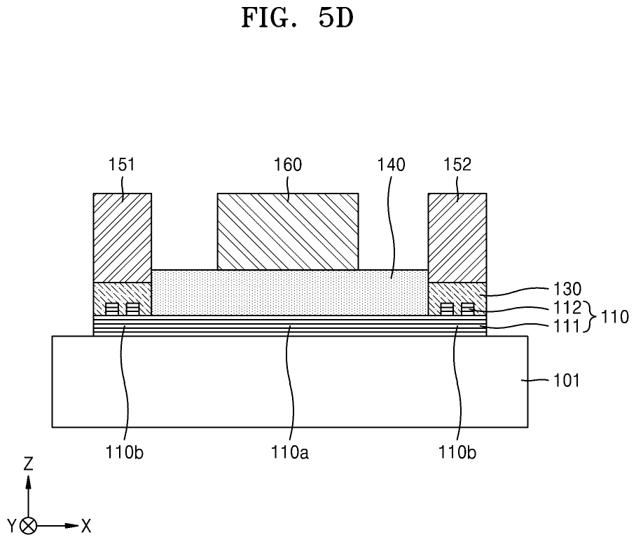

Hereinafter, a method of manufacturing the semiconductor device 100 according to the embodiment described above is described. FIGS. 5A to 5D are diagrams illustrating a method of manufacturing a semiconductor device according to an embodiment.

Referring to FIG. 5A, the 2D material layer 110 including the sheet member 111 extending along one plane (XY plane) and the protrusion 112 extending in one direction (Z direction) perpendicular to one plane (XY plane) is formed on the substrate 101. Here, the 2D material layer 110 includes a 2D semiconductor material having a polycrystalline structure. The substrate 101 may include various materials such as a semiconductor material, an insulating material, and a metal material.

The 2D semiconductor material may include a material having a bandgap equal to or greater than about 0.5 eV and equal to or smaller than 3.0 eV. For example, the 2D semiconductor material may include TMD or black phosphorus. However, the disclosure is not limited thereto.

TMD is a 2D material having semiconductor properties, and is a compound of a transition metal and a chalcogen element. Here, the transition metal may include, for example, at least one of Mo, W, Nb, V, Ta, Ti, Zr, Hf, Co, Tc, or Re, and the chalcogen element may include, for example, at least one of S, Se, or Te. As a specific example, TMD may include MoS₂, MoSe₂, MoTe₂, WS₂, WSe₂, WTe₂, ZrS₂, ZrSe₂, HfS₂, HfSe₂, NbSe₂, ReSe₂, etc. However, the disclosure is not limited thereto. Black phosphorus is a semiconductor material having a structure in which phosphorus (P) atoms are two-dimensionally combined. The 2D semiconductor material may be doped with a p-type dopant or an n-type dopant to control mobility.

The 2D material layer 110 may have a monolayer or multilayer structure, where each layer may have an atomic level thickness. The 2D material layer 110 may include, for example, one to ten layers. As a specific example, the 2D material layer 110 may include one to five layers. However, the disclosure is not limited thereto.

The sheet member 112 according to an embodiment may be formed by depositing and growing the 2D semiconductor material on a surface of the substrate 101. The deposition of the 2D semiconductor material may be performed, for example, by chemical vapor deposition (CVD), physical vapor deposition (PVD), etc., but this is merely an example.

According to an embodiment, the protrusion 112 may be formed to have a certain pattern on an upper portion of the sheet member 111 using a certain pattern mask process and an etching process. Also, according to another example, the protrusion 112 may be additionally deposited on a certain pattern region of the sheet member 111 using a certain process. Accordingly, the protrusion 112 may be formed to have a certain pattern on the upper portion of the sheet member 111. However, the disclosure is not limited thereto, and one or more protrusions 112 having an irregular pattern may be formed on one surface of the sheet member 111 in a process of manufacturing the sheet member 111.

Referring to FIG. 5B, the graphene layers 130 may be formed to cover a part of the sheet member 111 and the protrusion 112. According to an embodiment, the graphene layers 130 may be disposed in the second regions 110b respectively located on both sides of the 2D material layer 110. In this regard, graphene included in the graphene layers 130 may grow in one or more directions from a part of the sheet member 111 and a circumference of the protrusion 112.

As an example, the graphene layers 130 may grow such that a horizontal junction is formed in the first direction Lz with an upper surface of the sheet member 111 extending along one plane (XY plane). In addition, the graphene layers 130 may grow such that a vertical junction is formed with the protrusion 112 in one direction (Z direction) perpendicular to one plane (XY plane). Accordingly, the mixing region M in which the 2D material layer 110 and the graphene layers 130 coexist may be formed. As an example, the mixing region M may include a region of one or more layers and five or less layers. Also, as an example, the content of graphene in the mixing region M may be equal to or greater than about 20 vol % and equal to or smaller than about 80 vol %.

The graphene layers 130 according to an embodiment may be formed using low temperature chemical vapor deposition (LTCVD), inductively coupled plasma- chemical vapor deposition (ICP-CVD), low pressure chemical vapor deposition (LPCVD), atmospheric pressure chemical vapor deposition (APCVD), metal organic chemical vapor deposition (MOCVD), or plasma-enhanced chemical vapor deposition (PECVD), etc., but are not limited thereto.

Referring to FIG. 5C, the gate insulating layer 140 is formed in the first region 110a of the 2D material layer 110. The gate insulating layer 140 may include, for example, silicon nitride, etc., but is not limited thereto.

Referring to FIG. 5D, the gate electrode 160 is deposited on the gate insulating layer 140, and a source electrode and a drain electrode are deposited on the second region 110b of the 2D material layer 110. The gate electrode 160 may be provided on the first region 110a of the 2D material layer 110. The source electrode 151 and the drain electrode 152 are provided in the second region 110b of the 2D material layer 110, that is, the source region and the drain region. The source electrode 151 may be provided to contact the source region of the 2D material layer 110, and the drain electrode 152 may be provided to contact the drain region of the 2D material layer 110. The source electrode 151 and the drain electrode 152 may be spaced apart from each other on the 2D material layer 110. The gate electrode 160 may be spaced apart from the source electrode 151 and the drain electrode 152.

In the embodiments described above, the semiconductor devices 100 to 300 having a sheet channel structure have been described. However, the disclosure is not limited thereto, and for example, a semiconductor device (FinFET) having a Fin channel structure or a semiconductor device (multi bridge channel FET (MBCFET)) having a gate-all-around channel structure may be provided.

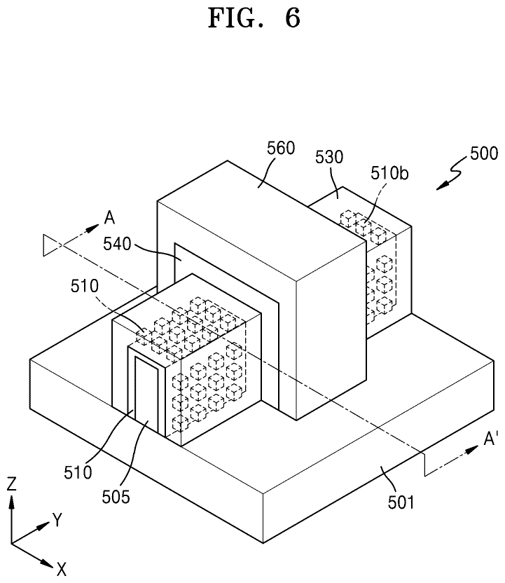

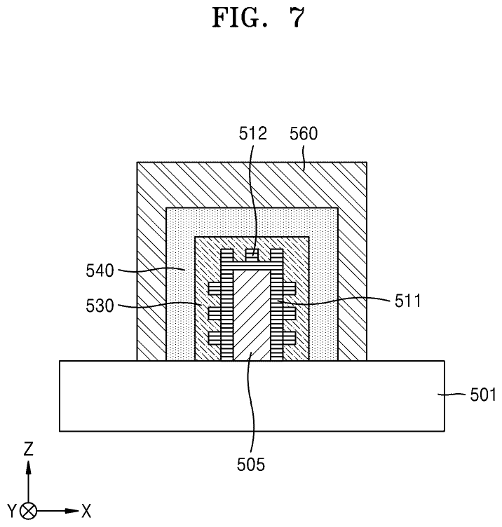

FIG. 6 is a perspective view illustrating a semiconductor device according to another embodiment, and FIG. 7 is a cross-sectional view taken along line A-A′ of FIG. 6.

Referring to FIGS. 6 and 7, an insulator 505 may be provided on a substrate 501 perpendicular to the substrate 501, and a 2D material layer 510 may be disposed as a channel layer to cover the insulator 505. Here, the 2D material layer 510 may have a fin-shape. The 2D material layer 510 according to an embodiment may include a first region 510a and second regions 510b provided on both sides of the first region 510a. The first region 510a may be a channel region located in the center of the 2D material layer 510. The second regions 510b may be source/drain regions located on both sides of the 2D material layer 510.

As an example, the 2D material layer 510 may include a sheet member 511 extending to cover the insulator 505 and a protrusion 512 formed in the second regions 510b. The graphene layer 530 according to an embodiment may be disposed to cover the sheet member 511 and the protrusion 512 in the second regions 510b. The 2D material layer 510 including the sheet member 511 and the protrusion 512 and the graphene layer 530 have been described above, and thus, detailed descriptions thereof are omitted.

A gate insulating layer 540 is provided in a first region 510a of the 2D material layer 510, and a gate electrode 560 is provided in the gate insulating layer 540. Here, the gate insulating layer 540 may be provided to surround the graphene layer 530, specifically, three surfaces of the first region 510a of the 2D material layer 510, and the gate electrode 560 may be provided to surround three surfaces of the gate insulating layer 540. Meanwhile, although not shown in the drawings, the source and drain electrodes may be provided in the second regions 510b of the 2D material layer 510.

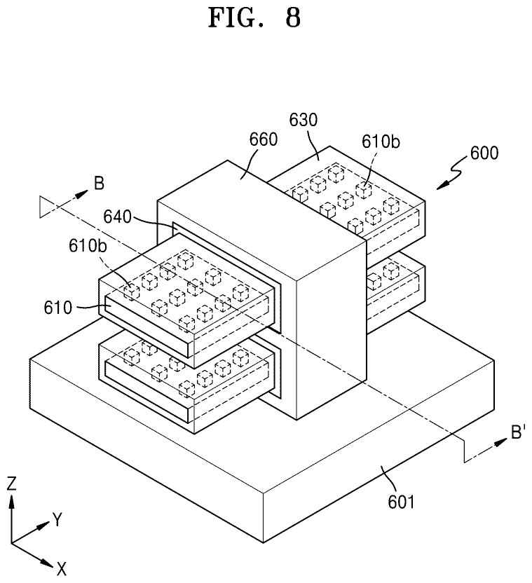

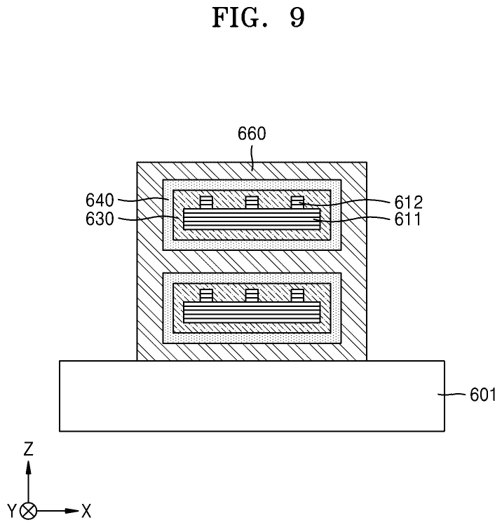

FIG. 8 is a perspective view illustrating a semiconductor device according to another embodiment, and FIG. 9 is a cross-sectional view taken along line B-B′ of FIG. 8.

Referring to FIGS. 8 and 9, one or more 2D material layers 610 are disposed on an upper portion of a substrate 601 to be spaced apart from the substrate 601. Here, each of the 2D material layers 610 may have a sheet shape disposed in parallel on the substrate 601. FIGS. 8 and 9 illustrate the two 2D material layers 610 vertically disposed on the upper portion of the substrate 601.

The 2D material layers 610 according to an embodiment may include a first region 610a and second regions 610b provided on both sides of the first region 610a. The first region 610a may be a channel region located in the center of the 2D material layer 610. The second regions 610b may be source/drain regions located on both sides of the 2D material layer 610.

As an example, the 2D material layer 610 may include a sheet member 611 extending along one plane (XY plane) and a protrusion 612 formed on the second regions 610b. The graphene layer 630 according to an embodiment may be disposed to cover the sheet member 611 and the protrusion 612 in the second regions 610b. The 2D material layer 610 including the sheet member 611 and the protrusion 612 and the graphene layer 630 have been described above, and thus, detailed descriptions thereof are omitted.

A gate insulating layer 640 is provided in the first region 610a of the 2D material layer 610, and a gate electrode 660 is provided in the gate insulating layer 640. Here, the gate insulating layer 640 is provided to surround the graphene layer 630, specifically, four surfaces of the first region 610a of the 2D material layer 610, and the gate electrode 660 may be provided to surround four surfaces of the gate insulating layer 640. Although not shown in the drawings, the source and drain electrodes may be provided in the second regions 610b of the 2D material layer 610. Meanwhile, an insulator (not shown) may be disposed on the substrate 601 in parallel to the substrate 601, and the graphene layer 630 may be provided to surround the insulator.

The semiconductor devices 100 to 600 described above may be applied to, for example, a memory device such as a DRAM device. The memory device may have a structure in which each of the semiconductor devices 100 to 600 described above is electrically connected to a capacitor. Also, the semiconductor devices 100 to 600 may be applied to various electronic devices. For example, the semiconductor devices 100 to 600 described above may be used to perform arithmetic operations, execute programs, and maintain temporary data in electronic devices such as a mobile device, a computer, a notebook computer, a sensor, a network device, a neuromorphic device, etc.

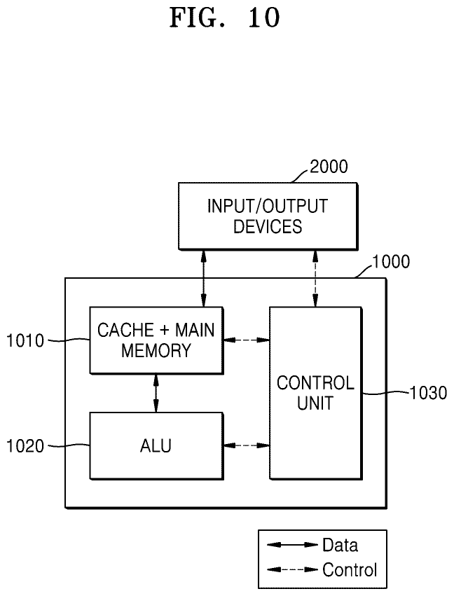

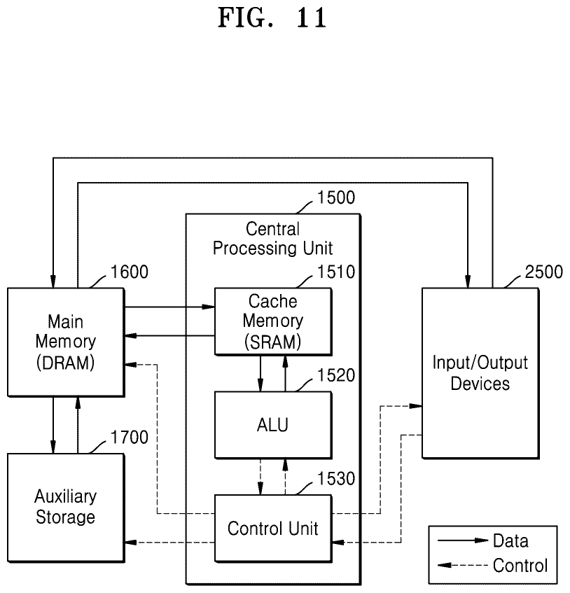

FIGS. 10 and 11 are conceptual diagrams schematically illustrating an electronic device architecture that may be applied to an electronic device according to an embodiment.

Referring to FIG. 10, an electronic device architecture 1000 may include a memory unit 1010, an arithmetic logic unit (ALU) 1020, and a control unit 1030. The memory unit 1010, the ALU 1020, and the control unit 1030 may be electrically connected to each other. For example, the electronic device architecture 1000 may be implemented as one chip including the memory unit 1010, the ALU 1020, and the control unit 1030.

Specifically, the memory unit 1010, the ALU 1020, and the control unit 1030 may be interconnected through a metal line in an on-chip to directly communicate with each other. The memory unit 1010, the ALU 1020, and the control unit 1030 may be monolithically integrated on one substrate to configure one chip. Input/output devices 2000 may be connected to the electronic device architecture (chip) 1000.

The ALU 1020 and the control unit 1030 may each independently include the semiconductor devices 100 to 600 described above, and the memory unit 1010 may include the semiconductor devices 100 to 600, a capacitor, or a combination thereof. The memory unit 1010 may include both a main memory and a cache memory. The electronic device architecture (chip) 1000 may be an on-chip memory processing unit.

Referring to FIG. 11, a cache memory 1510, an ALU 1520, and a control unit 1530 may configure a central processing unit (CPU) 1500. The cache memory 1510 may be formed as a static random access memory (SRAM), and may include the semiconductor devices 100 to 600 described above. Separately from the CPU 1500, a main memory 1600, an auxiliary storage 1700 may be provided. The main memory 1600 may include a dynamic random access memory (DRAM) device. Input/output devices 2500 may be connected to the CPU 1500, main memory 1600, and auxiliary storage 1700. The auxiliary storage 1700 may include the semiconductor devices 100 to 600 described above.

In some cases, an electronic device architecture may be implemented in a form in which computing unit devices and memory unit devices are adjacent to each other in a single chip without distinction of sub-units. Although the embodiments have been described above, these are merely an example, and various modifications are possible therefrom by those of ordinary skill in the art.

The semiconductor device according to an embodiment may have excellent performance even at a thin thickness equal to or less than 1 nm by using a 2D semiconductor material as a channel layer, and may also reduce a short channel effect, thereby overcoming the limitation of performance degradation due to the miniaturization of the semiconductor device.

In addition, the graphene layers of sem imetal property may be disposed between the 2D material layer configuring the channel layer and the source electrode and the drain electrode including a metal material, and thus, the semiconductor device according to an embodiment may limit and/or suppress Fermi-level pinning of the 2D material layer. Accordingly, the semiconductor device according to an embodiment may reduce the contact resistance in the source region and the drain region of the 2D material layer.

In addition, in the semiconductor device according to an embodiment, the 2D material layer configuring the channel layer has a flat plate structure extending along one plane and the protrusion protruding from one plane, and thus, graphene may grow in a lateral direction of the protrusion provided in the 2D material layer as well as in a vertical direction. Accordingly, the contact region between the graphene layer and the 2D material layer is improved, and thus, the contact resistance in the source region and the drain region of the 2D material layer may be reduced.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a two-dimensional (2D) material layer including a 2D semiconductor material having a polycrystalline structure,
the 2D material layer including a sheet member and a protrusion, the sheet member extending along one plane and the protrusion extending in one direction perpendicular to the one plane;
a source electrode and a drain electrode spaced apart from each other on the 2D material layer;
a gate insulating layer and a gate electrode on the 2D material layer between the source electrode and the drain electrode; and
graphene layers on both sides of the gate insulating layer, the graphene layers covering a part of the sheet member and the protrusion.

2. The semiconductor device of claim 1, wherein
the graphene layers are on the part of the sheet member and an upper portion of the protrusion through a horizontal junction along the one plane and a vertical junction in the one direction perpendicular to the one plane.

3. The semiconductor device of claim 1, wherein
the 2D material layer comprises a first region and second regions,
the first region corresponds to the gate electrode, and
the second regions correspond to the source electrode and the drain electrode,
the protrusion is in the second regions, and
the graphene layers are in the second regions between the source electrode and the 2D material layer and between the drain electrode and the 2D material layer.

4. The semiconductor device of claim 3, wherein a thickness of the sheet member in the first region and a thickness of the sheet member in the second regions are equal to each other.

5. The semiconductor device of claim 3, wherein
a thickness of the sheet member in the second regions exceeds a thickness of the sheet member in the first region.

6. The semiconductor device of claim 1, further comprising:
spacers, wherein
the 2D material layer comprises a first region and second regions,
the first region corresponds to the gate electrode, and
the second regions correspond to a region between the source electrode and the gate electrode and a region between the drain electrode and the gate electrode,
the protrusion is in the second regions,
the graphene layers are between the 2D material layer and the spacers in the second regions, and
the spacers are between the source electrode and the gate electrode and between the drain electrode and the gate electrode in the second regions.

7. The semiconductor device of claim 6, wherein the graphene layers extend under the source electrode and the drain electrode.

8. The semiconductor device of claim 1, wherein the 2D semiconductor material comprises a material having a bandgap greater than or equal to about 0.5 eV and less than or equal to about 3.0 eV.

9. The semiconductor device of claim 1, wherein the 2D semiconductor material comprises transition metal dichalcogenide (TMD) or black phosphorus.

10. The semiconductor device of claim 1, wherein
the graphene layers comprise graphene, and
the graphene has a crystal size of about 0.5 nm or more and about 500 nm or less.

11. The semiconductor device of claim 1, wherein,
the graphene layers comprise graphene,
the graphene has a ratio of carbons having a sp2 combination structure with respect to all carbons of about 50% or more and about 99% or less.

12. The semiconductor device of claim 1, wherein, in a mixing region where the 2D material layer and the graphene layers coexist in the one direction, a content of graphene in the graphene layers is about 20 vol % or more and about 80 vol % or less.

13. An electronic device comprising:
the semiconductor device of claim 1.

14. A method of manufacturing a semiconductor device, the method comprising:
forming a two-dimensional (2D) material layer on a substrate,
the 2D material layer including a 2D semiconductor material having a polycrystalline structure,
the 2D material layer including a sheet member and a protrusion, the sheet member extending along one plane and the protrusion extending in one direction perpendicular to the one plane;
forming a graphene layer covering a part of the sheet member and the protrusion;
forming a gate insulating layer and a gate electrode on the 2D material layer; and
forming a source electrode and a drain electrode spaced apart from each other on the 2D material layer.

15. The method of claim 14, wherein the forming the graphene layer includes growing graphene in one or more directions from the part of the sheet member and a circumference of the protrusion.

16. The method of claim 15, wherein the protrusion is a single protrusion or a plurality of protrusions.

17. The method of claim 15, wherein
the 2D material layer comprises a first region and second regions,
the first region corresponds to the gate electrode, and
the second regions correspond to the source electrode and the drain electrode,
the protrusion is in the second regions, and
the graphene layer is in the second regions between the source electrode and the 2D material layer and between drain electrode and the 2D material layer.

18. The method of claim 14, wherein the 2D semiconductor material comprises a material having a bandgap of about 0.5 eV to about 3.0 eV.

19. The method of claim 14, wherein
the graphene layer comprises graphene, and
the graphene has a crystal size of about 0.5 nm to about 500 nm.

20. The method of claim 14, wherein
the graphene layer comprises graphene, and
the graphene has a ratio of carbons having a sp2 combination structure with respect to all carbons of about 50% to about 99%.
